(19) United States
(12) Patent Application Publication
(10) Pub. No.: US 2005/0287742 A1
(43) Pub. Date: Dec. 29, 2005

(54) Method of manufacturing a nonvolatile semiconductor memory device

(76) Inventor: Yun-Seung Kang, Seoul (KR)

Correspondence Address: MARGER JOHNSON & McCOLLOM, P.C., 1030 S.W. Morrison Street, Portland, OR, 97205, US

(21) Appl. No.: 11/168,178

(22) Filed: Jun. 27, 2005

(30) Foreign Application Priority Data
Jun. 28, 2004 (KR) 2004-49074

(51) Int. Cl. H01L 21/336

(52) U.S. Cl. 438/257

(57) ABSTRACT

In a method of manufacturing a nonvolatile semiconductor memory device, a preliminary floating gate is formed on a substrate having an active region and an inactive region that extend in a first direction. A dielectric layer and a control gate layer are formed on the substrate. A control gate, a dielectric layer, and a remaining pattern structure are formed by etching the control gate layer and the dielectric layer in a second direction until the preliminary floating gate is partially exposed. The floating gate is formed by etching the preliminary floating gate and the remaining pattern structure until the silicon substrate is exposed. The remaining pattern structure may prevent the isolation layer defining the inactive region from being damaged, thereby suppressing a leakage current in the nonvolatile semiconductor memory device.

### CROSS REFERENCE TO RELATED APPLICATIONS

This application claims priority from Korean Patent Application No. 2004-49074, filed Jun. 28, 2004, the content of which is incorporated by reference in its entirety for all purposes.

### BACKGROUND

1. Technical Field

This disclosure relates to a method of manufacturing a nonvolatile semiconductor memory device, and in particular, to a method of manufacturing a nonvolatile semiconductor memory device that includes a floating gate, a dielectric layer, and a control gate.

2. Description of the Related Art

Semiconductor memory devices may be characterized as volatile or non-volatile. Volatile semiconductor memory devices include dynamic random access memory (DRAM) devices and static random access memory (SRAM) devices. Non-volatile semiconductor memory device include, for example, flash memory devices. Volatile semiconductor memory devices lose stored information when power to the device is turned off, whereas nonvolatile semiconductor memory devices maintain stored information after the power supply is turned off.

Since nonvolatile semiconductor memory devices retain data stored within without a continuous power supply, the nonvolatile devices, and in particular, flash memory devices, have been widely employed in a variety of electronic devices.

Flash memory devices include a memory cell in which data is stored. The memory cell generally includes a floating gate, a dielectric layer, and a control gate. The floating gate is formed on a silicon substrate where a gate oxide layer is formed. A dielectric layer is formed on the floating gate. The control gate is formed on the dielectric layer. The data may be stored in the memory cell by providing electrons into the floating gate, whereas the data may be deleted from the memory cell by extracting the electrons from the floating gate. Here, the dielectric layer prevents the electrons from easily moving into and/or from the floating gate. The dielectric layer also transfers a voltage applied to the control gate.

FIG. 1 is a cross sectional view illustrating a conventional nonvolatile semiconductor memory device.

Referring to FIG. 1, a gate oxide layer 12 and a floating gate 14 are formed on a semiconductor substrate 10. An isolation layer (not shown) may also be formed on the semiconductor substrate 10, typically by using a shallow trench isolation (STI) process. A dielectric layer 22 is formed on the floating gate 14, the dielectric layer including a lower oxide layer, a nitride layer, and an upper oxide layer. A control gate 24 is formed on the dielectric layer 22. Thus, the nonvolatile semiconductor memory device includes the floating gate 14, the dielectric layer 22, and the control gate 24.

Data may be stored in the nonvolatile semiconductor memory device by providing electrons into the floating gate 24. The data may be deleted from the nonvolatile semiconductor memory device by extracting the electrons from the floating gate 24. The dielectric layer 22 prevents the electrons from being easily moving into and/or from the floating gate 24. The dielectric layer 22 also transfers a voltage that is applied to the control gate 24 to the floating gate 14.

The coupling constant R is a measure of how efficiently the dielectric layer 22 transfers the voltage applied to the control gate 24 to the floating gate 14. The coupling constant R is generally given according to the following equation 1.
R=C_{ONO}/(C_{ONO}+C_{TO}) (1)
In equation 1, C_{ONO} indicates a capacitance of the dielectric layer 22, and C_{TO} represents a capacitance of the gate oxide layer 12.

To increase the coupling constant R, the capacitance C_{ONO} of the dielectric layer 22 should be augmented. The capacitance C is given in accordance with the following equation 2.
C=ε×(A/T) (2)
In equation 2, ε is the dielectric constant, A is the area of the dielectric layer 22, and T is the thickness of the dielectric layer 22.

As a result, in order to increase the capacitance C, the area A of the dielectric layer 22 should be increased or the thickness of the dielectric layer 22 should be decreased, which results in an increased coupling constant R.

A method of increasing the area of a dielectric layer is disclosed in Japanese Laid Open Patent Publication No. 1993-291586. According to this method, a silicon substrate includes an isolation layer. The isolation layer has an upper surface that is lower than that of the silicon substrate. A floating gate is formed on a portion of the silicon substrate. The floating gate is formed by partially etching a preliminary floating gate. The height of the floating gate is greater than that of the isolation layer. A dielectric layer and a control gate are sequentially formed on the floating gate. Since the height of the floating gate is greater than that of the isolation layer, the area of the dielectric layer formed on the floating gate is also large. As a result, a high coupling constant may be obtained.

However, since the height of the preliminary floating gate is greater than that of the isolation layer, the isolation layer may be over-etched during the etching process for forming the floating gate. As a result, a void or a punch causing a leakage current to the silicon substrate may be formed in the isolation layer, thereby deteriorating the electrical characteristics of the nonvolatile semiconductor memory device.

Embodiments of the invention address these and other disadvantages of the conventional art.

### SUMMARY

Embodiments of the invention prevent an isolation layer from being damaged during an etching process that is used to form a floating gate, thus providing a method of manufacturing a nonvolatile semiconductor memory device having improved electrical characteristics.

### BRIEF DESCRIPTION OF THE DRAWINGS

Other aspects and advantages of the invention will become readily apparent by reference to the following detailed description when considered in conjunction with the accompanying drawings wherein.

FIG. 1 is a cross sectional diagram illustrating a conventional nonvolatile semiconductor memory device.

FIG. 2 is a flow chart that describes some exemplary processes for a method of manufacturing a nonvolatile semiconductor memory device in accordance with some embodiments of the invention.

FIGS. 3 to 7 are perspective diagrams illustrating a method of manufacturing a nonvolatile semiconductor memory device in accordance with some embodiments of the invention.

FIGS. 8 to 12 are perspective diagrams illustrating a method of manufacturing a nonvolatile semiconductor memory device in accordance with some embodiments of the invention.

FIGS. 13 to 16 are perspective diagrams illustrating a method of manufacturing a nonvolatile semiconductor memory device in accordance with some embodiments of the invention.

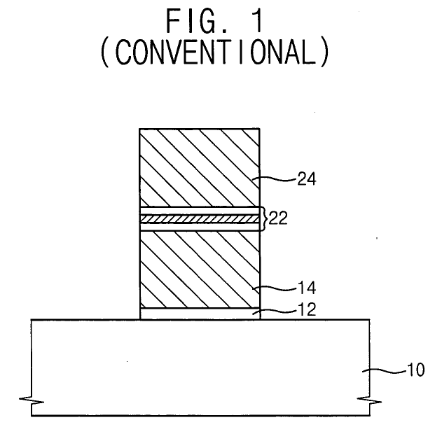

### DETAILED DESCRIPTION

Aspects of the invention are described more fully hereinafter with reference to the accompanying drawings, in which several exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could alternatively be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

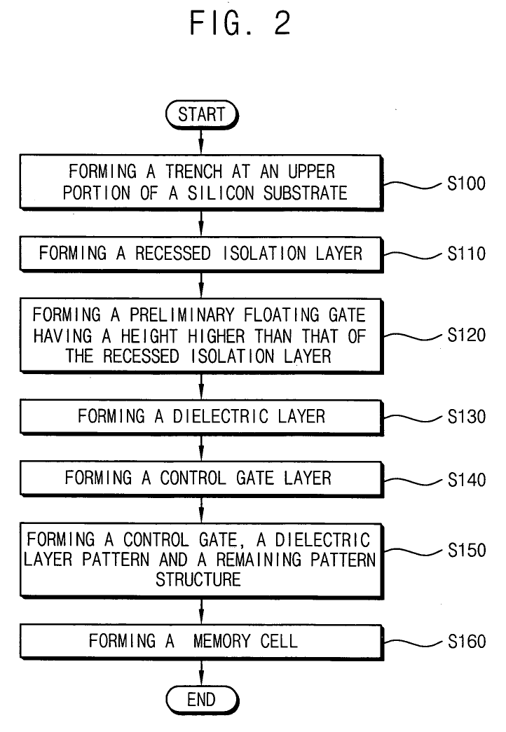

FIG. 2 is a flow chart that describes some exemplary processes for a method of manufacturing a nonvolatile semiconductor memory device in accordance with some embodiments of the invention.

Referring to FIG. 2, in process S100, a trench is formed in an upper portion of a silicon substrate. Particularly, after a first mask pattern is formed on the substrate, a portion of the substrate exposed by the first mask pattern is selectively etched to thereby form the trench extending in a first direction. Then, the first mask pattern is removed from the substrate.

The trench may correspond to an inactive region of the substrate, whereas a portion of the substrate positioned between adjacent trenches may correspond to an active region. That is, the trench defines the active region and the inactive region of the substrate. Alternatively, the substrate may also be divided into a first region and a second region. Here, a memory cell of a nonvolatile semiconductor device may be formed in the first region, whereas no layers may be positioned in the second region. Namely, portions of the layers positioned in the second region may be removed from the second region.

In process S110, a recessed isolation layer is formed to partially fill the trench. The uppermost part of the recessed isolation layer is disposed lower than the uppermost part of the trench. In other words, an upper surface of the recessed isolation is lower than an upper surface of the active region of the substrate. Since the recessed isolation layer is formed in the trench, the recessed isolation layer also extends in the first direction.

For example, an oxide, which easily fills up a gap, may be deposited on the substrate by a chemical vapor deposition (CVD) process, thereby forming an oxide layer on the substrate. At this point, the trench is completely filled with the oxide layer. The oxide layer may include a high density plasma-chemical vapor deposition (HDP-CVD) oxide. Then, the oxide layer is planarized by a chemical mechanical polishing (CMP) process, an etch back process, or a combined CMP/etch back process until the substrate is exposed, thereby forming an isolation layer in the trench. Subsequently, the isolation layer is partially etched to form the recessed isolation layer in the trench, where an upper surface of the recessed isolation layer is lower than an upper surface of the substrate.

In process S120, a preliminary floating gate is formed on a gate oxide layer to enclose the active region. The preliminary floating gate has a height that is greater than that of the recessed isolation layer. Since the recessed isolation layer is formed in the trench, an upper portion of the active region protrudes above the recessed isolation layer. The preliminary floating gate encloses this protruding upper portion of the active region.

Before forming the preliminary floating gate, the upper portion of the active region may be oxidized to form the gate oxide layer. The gate oxide layer may be formed by a radical oxidation process. For example, the gate oxide layer may be formed using an oxygen (O₂) gas, a hydrogen (H₂) gas, and a nitrogen (N₂) gas at a temperature above about 800° C. under a pressure of below about 1 Torr.

A first preliminary polysilicon layer is formed on the substrate to cover the gate oxide layer and the recessed isolation layer. The first preliminary polysilicon layer may be formed by a low pressure chemical vapor deposition (LPCVD) process. Then, impurities are doped into the first preliminary polysilicon layer to form a first polysilicon layer on the substrate. The impurities may be doped using a phosphorus oxychloride (POCl₃) diffusion process, an ion implantation process, an in-situ doping process, etc.

After an etching mask pattern for forming the preliminary floating gate is formed on the first polysilicon layer, a portion of the first polysilicon layer exposed by the etching mask pattern is selectively etched so that the preliminary floating gate is formed on the gate oxide layer. The preliminary floating gate extends over the recessed isolation layer so that the width of the preliminary floating gate is wider than that of the active region. The preliminary floating gate encloses the upper portion of the active region because the upper portion of the active region protrudes upwards from the recessed isolation layer.

In process S130, after the etching mask is removed, a dielectric layer is formed on the substrate to cover the preliminary floating gate. To form the dielectric layer, a first oxide layer, a nitride layer, and a second oxide layer are sequentially formed on the substrate. Thus, the dielectric layer has an ONO (oxide/nitride/oxide) structure. The first and the second oxide layers may include silicon oxide. The first and second oxide layers may be formed by a thermal oxidation process, a radical oxidation process, a low pressure chemical vapor deposition (LPCVD) process, etc. The first and second oxide layers may be annealed in-situ using a nitrous oxide gas (N₂O) gas or a nitric oxide (NO) gas so that the structures of the first and second oxide layers have an increased density.

In process S140, a control gate layer is formed on the dielectric layer. In particular, after a second preliminary polysilicon layer is formed on the dielectric layer, impurities are doped into the second preliminary polysilicon layer so that a second polysilicon layer that serves as the control gate layer is formed on the dielectric layer. The second preliminary polysilicon layer may be formed by an LPCVD process, and the impurities may be doped by a phosphorus oxychloride diffusion process, an ion implantation process, an in-situ doping process, etc.

In process S150, the control gate layer and the dielectric layer are partially etched to simultaneously form a control gate, a dielectric layer pattern, and a remaining pattern structure. The control gate layer and the dielectric layer may be etched using a dry etching process. The remaining pattern structure may include a first remaining pattern and a second remaining pattern. The first remaining pattern is formed simultaneously along with the control gate, and the second remaining pattern is formed simultaneously along with the dielectric layer pattern. The remaining pattern structure is formed between the preliminary floating gates.

In particular, after a second mask pattern is formed on the control gate layer positioned in a second region of the substrate, a portion of the control gate layer exposed by the second mask pattern is etched until the dielectric layer is exposed. Hence, the control gate and the first remaining pattern are formed simultaneously. The first remaining pattern is formed over the recessed isolation layer and between the preliminary floating gates that extend along a first direction in the first region. The first remaining pattern may have a height of about 50 to about 150 Å. In some embodiments of the invention, the height of the first remaining pattern is lower than an entire height of the recessed isolation layer and the preliminary floating gate.

Sequentially, a portion of the dielectric layer positioned between the preliminary floating gates is partially etched to form the dielectric layer pattern and the second remaining pattern. The second remaining pattern is formed beneath the first remaining pattern, and the dielectric layer pattern is positioned beneath the control gate. Therefore, the entire height of the remaining pattern structure and the recessed isolation layer is greater than the height of the preliminary floating gate. When the entire height of the remaining pattern structure and the recessed isolation layer is less than the height of the preliminary floating gate, a void or a punch causing a leakage current to the substrate may be formed in the recessed isolation layer during a subsequent etching process for forming a floating gate.

The remaining pattern structure may protect the recessed isolation layer during the subsequent etching process for simultaneously removing the preliminary floating gate and the remaining pattern structure. When the remaining pattern structure is not sufficiently thick, it may be removed earlier than the preliminary floating gate so that the recessed isolation layer may be damaged in the subsequent etching process. As a result, the void or the punch may result in the recessed isolation layer, thereby causing the leakage current to the substrate.

Alternatively, portions of the control gate and the dielectric layer may be fully etched so that the remaining pattern structure is not formed on the recessed isolation layer. A sacrificial pattern is then formed on the recessed isolation layer and between the floating gates. The sacrificial pattern may be formed using photoresist.

In process S160, a portion of the preliminary floating gate exposed by the control gates is etched to form the floating gate, thereby completing a memory cell of the nonvolatile semiconductor memory device. The preliminary floating gate may be partially etched by a dry etching process. The memory cell includes the floating gate, the dielectric layer, and the control gate. In particular, portions of the preliminary floating gate and the remaining pattern structure exposed by the control gate are etched until the gate oxide layer and the recessed isolation layer are exposed. The portions of the preliminary floating gate and the remaining pattern structure in the second region may be removed by a dry etching process.

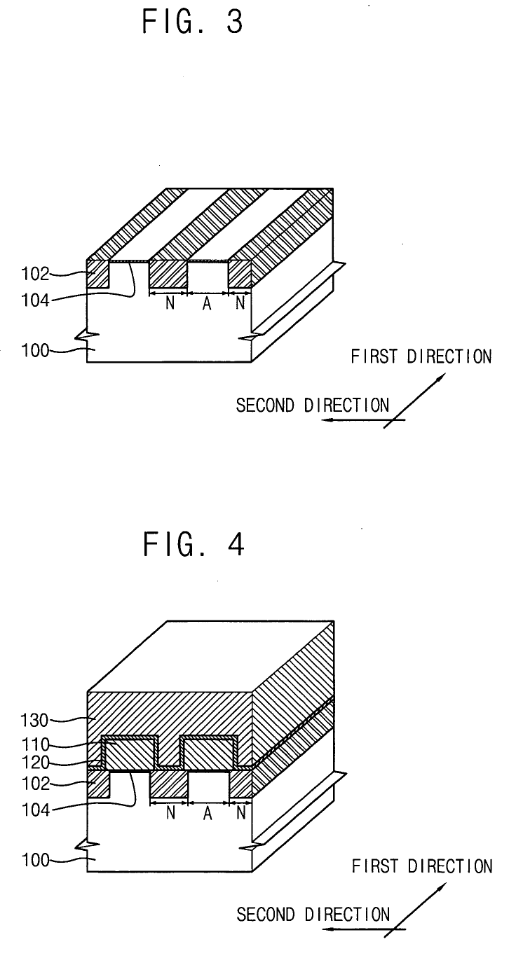

FIGS. 3 to 7 are perspective diagrams illustrating a method of manufacturing a nonvolatile semiconductor memory device in accordance with some embodiments of the invention.

Referring to FIG. 3, an isolation layer 102 is formed on a silicon substrate 100 to define an inactive region N and an active region A. A first portion of the substrate 100 where the isolation layer 102 is positioned corresponds to the inactive region N. In addition, a second portion of the substrate 100 between the inactive regions N correspond to the active region A. The active regions A and inactive regions N are alternately encountered as one moves along the second direction of the substrate.

In order to form the isolation layer 102, a first mask pattern (not shown) is formed on the first portion of the substrate 100 to expose the second portion of the substrate, the exposed second portion of the substrate is then etched to form a trench in the second portion of the substrate. The trench may be positioned in the inactive region N of the substrate 100. The length of the trench is parallel to the first direction, that is, the trench extends along the first direction.

After the first mask pattern is removed from the substrate 100, an oxide layer is formed on the substrate 100 to fill the trench. The oxide layer may be formed on the substrate 100 by a CVD process. Additionally, the oxide layer may include an oxide having a good gap-filling property such as HDP-CVD oxide.

The oxide layer is partially removed using a CMP process, an etch back process, or a combined CMP/etch back process until the first portion of the substrate 100 is exposed. At this point, the isolation layer 102 as shown in FIG. 3 is formed.

The exposed first portion of the substrate 100 is oxidized so that a gate oxide layer 104 is formed on the first portion of the substrate 100. The gate oxide layer 104 may be formed using a radical oxidation process. For example, the gate oxide layer 104 may be formed using an oxygen (O₂) gas, a hydrogen (H₂) gas, and a nitrogen (N₂) gas at a temperature above about 800° C. and under a pressure below about 1 Torr.

Referring to FIG. 4, a preliminary floating gate 110, a dielectric layer 120, and a control gate layer 130 are sequentially formed on the silicon substrate 100. Here, the preliminary floating gate 110 has a height greater than that of the isolation layer 102.

To form the preliminary floating gate 110, a first preliminary polysilicon layer (not shown) is formed on the substrate 100 including the gate oxide layer 104 and the isolation layer 102. Next, impurities are doped in the preliminary polysilicon layer to form a first polysilicon layer (not shown).

A first etching mask (not shown) is formed on the substrate 100 to expose a portion of the first polysilicon layer. The exposed portion of the first polysilicon layer is then etched to form the preliminary floating gate 110 on the gate oxide layer 104. The preliminary floating gate 110 is positioned above the active region A, and partially extends into the neighboring inactive regions N, over the isolation layer 102. That is, the preliminary floating gate 110 has a width that is greater than a width of the active region A. Next, the first etching mask is removed from the substrate 100.

A lower oxide layer, a nitride layer, and an upper oxide layer are sequentially formed on the substrate 100 to cover the preliminary floating gate 110. Hence, a dielectric layer 120 having an ONO (oxide/nitride/oxide) structure is uniformly formed on the substrate 100. The lower and upper oxide layers may include silicon oxide, and the nitride layer may include silicon nitride.

To form the control gate layer 130, a second polysilicon layer is formed on the dielectric layer 120. The thickness of the control gate layer 130 is sufficient to completely cover the preliminary floating gates 110 and a gap between the preliminary floating gates.

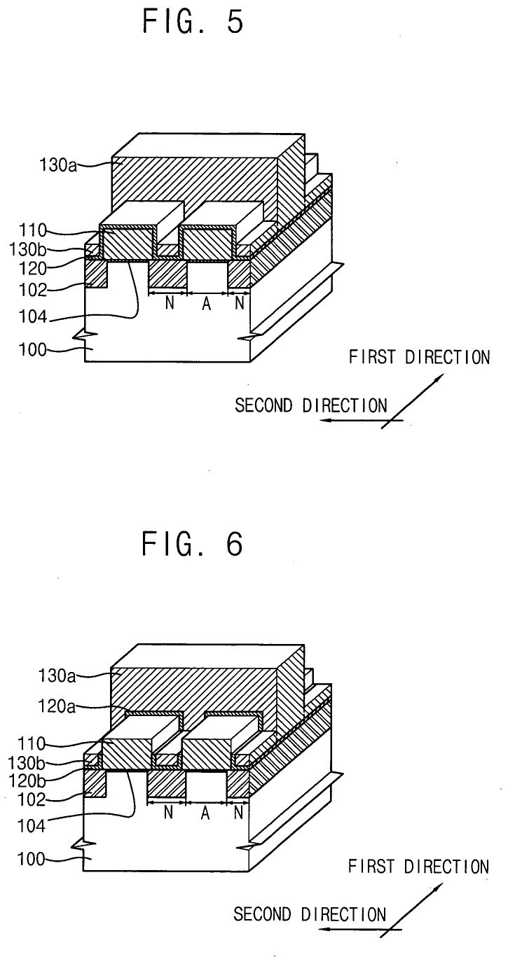

Referring to FIG. 5, after a second etching mask (not shown) is formed on the control gate layer 130, the control gate layer 130 is partially etched to form a control gate 130a on the dielectric layer 120 and to simultaneously form a first remaining pattern 130b on the dielectric layer and over the isolation layer 102. The control gate layer 130 may be etched using a dry etching process.

The control gate 130a is formed over the preliminary floating gates 110 in a second direction that is substantially perpendicular to the first direction. The first remaining pattern 130b is positioned between the preliminary floating gates 110 along the first direction. The first remaining pattern 130b has a height that is lower than that of the preliminary floating gate 110. Preferably, the control gate layer 130 is etched such that the first remaining pattern 130b has a thickness of about 50 to about 150 Å. When the first remaining pattern 130b is formed between the preliminary floating gates 110, a first portion of the dielectric layer 120 is exposed along the first direction whereas a second portion of the dielectric layer 120 is not exposed because the control gate 130a is formed thereon.

Referring to FIG. 6, the first portion of the dielectric layer 120 is etched until a portion of the preliminary floating gate 110 is exposed. The first portion of the dielectric layer 120 may be etched by a dry etching process. Removal of the first portion of the dielectric layer 120 simultaneously forms a second remaining pattern 120b and a dielectric layer pattern 120a. The second remaining pattern 120b is positioned between the first remaining pattern 130b and a sidewall of the preliminary floating gate 110 and between the first remaining pattern 130b and the isolation layer 102. The dielectric layer pattern 120a substantially corresponds to the second portion of the dielectric layer 120. Thus, the dielectric layer pattern 120a is positioned between the preliminary floating gate 110 and the control gate 130a. The dielectric layer pattern 120a is formed in the second direction, whereas the second remaining pattern 120b is formed along the first direction. Hence, the second remaining pattern 120b is substantially perpendicular to the dielectric layer pattern 120a. When the second remaining pattern 120b is formed, a remaining pattern structure that includes the first and second remaining patterns 130b and 120b is formed on the isolation layer 102 between the preliminary floating gates 110.

According to these embodiments of the invention, the entire height of the remaining pattern structure and the preliminary floating gate 110 is greater than that of the isolation layer 102. If the entire height of the remaining pattern structure and the preliminary floating gate 110 had been less than a height of the isolation layer 102, a void or a punch-through might be caused in the isolation layer during a subsequent etching process, resulting in unwanted leakage current. That is, if the remaining pattern structure is not sufficiently thick, the remaining pattern structure may be removed earlier than the preliminary floating gate 110, exposing the isolation layer 102. Subsequently, a void or a punch-through may be formed in the isolation layer 102.

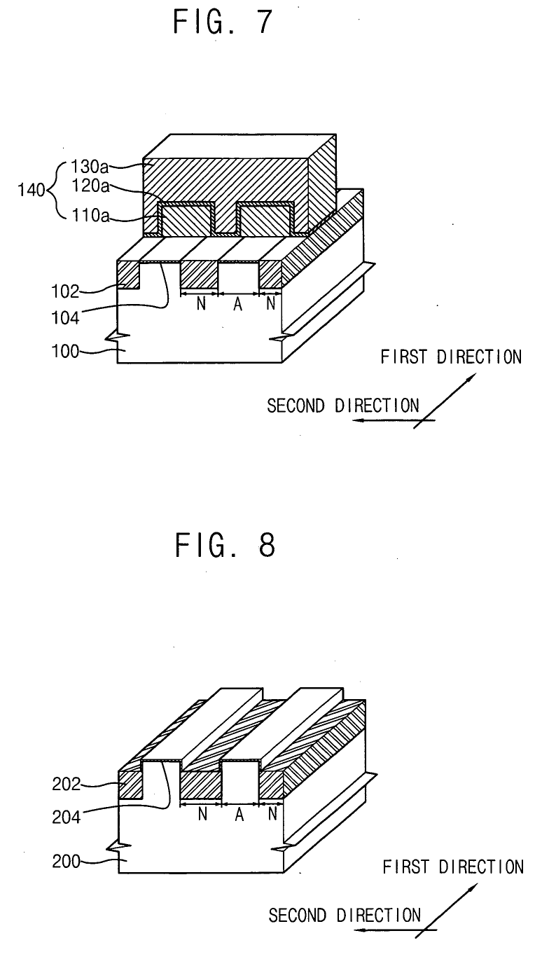

Referring to FIG. 7, the exposed portion of the preliminary floating gate 110 and the remaining pattern structure are etched until the gate oxide layer 104 and the isolation layer 102 are exposed. Thus, the floating gate 110a is formed under the control gate 130a. The floating gate 110a is positioned on the active region A of the substrate 100 and extends lengthwise in the first direction. The dielectric layer pattern 120a is interposed between the floating gate 110a and the control gate 130a. Therefore, there is formed on the substrate 100 a stacked memory cell 140 of the nonvolatile semiconductor memory device, the memory cell including the control gate 130a, the dielectric layer pattern 120a, and the floating gate 110a. Since the isolation layer 102 does not have a void or punch-through, leakage currents from the stacked memory cell 140 to the substrate 100 can be avoided.

FIGS. 8 to 12 are perspective diagrams illustrating a method of manufacturing a nonvolatile semiconductor memory device in accordance with some embodiments of the invention.

Referring to FIG. 8, a recessed isolation layer 202 that defines an inactive region N and an active region A is formed on a silicon substrate 200. The recessed isolation layer 202 extends lengthwise in a first direction. The active region A may correspond to a first portion of the substrate 200 on which a gate oxide layer 204 is formed, and the inactive region N may correspond to a second portion of the substrate 200 where the recessed isolation layer 202 is positioned.

To form the recessed isolation layer 202, the second portion of the substrate 200 is etched to form a trench, as was described above with respect to FIG. 3. The trench extends lengthwise in the first direction and may be located in the inactive region N. After an oxide layer (not shown) that easily fills up a gap is formed on the substrate 200 to fill the trench, an upper portion of the oxide layer is removed until the first portion of the substrate 200 is exposed. The oxide layer may be formed on the substrate 200 with HDP-CVD oxide in a CVD process. The oxide layer may be partially removed by a CMP process, an etch back process, or a combined CMP/etch back process. Thus, an isolation layer (not shown) is formed to completely fill up the trench. The isolation layer is partially etched to form the recessed isolation layer 202 in the trench. Namely, an upper portion of the isolation layer is removed to form the recessed isolation layer 202, where the thickness of the recessed isolation layer is less than an overall depth of the trench. When the recessed isolation layer 202 is formed in the trench, an upper portion and an upper sidewall of the active region A (i.e., the first portion of the substrate 200) are exposed.

The exposed upper portion and the exposed sidewall of the active region A are oxidized to form a gate oxide layer 204 that encloses the upper portion of the active region A. That is, the gate oxide layer 204 is formed on the exposed upper portion and the exposed sidewall of the active region A. The gate oxide layer 204 may be formed on the active region A by a thermal oxidation process.

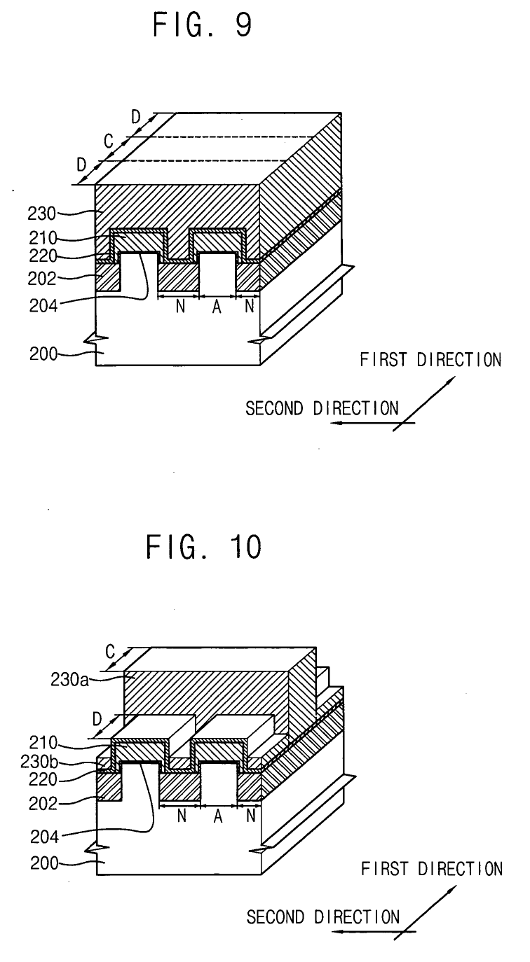

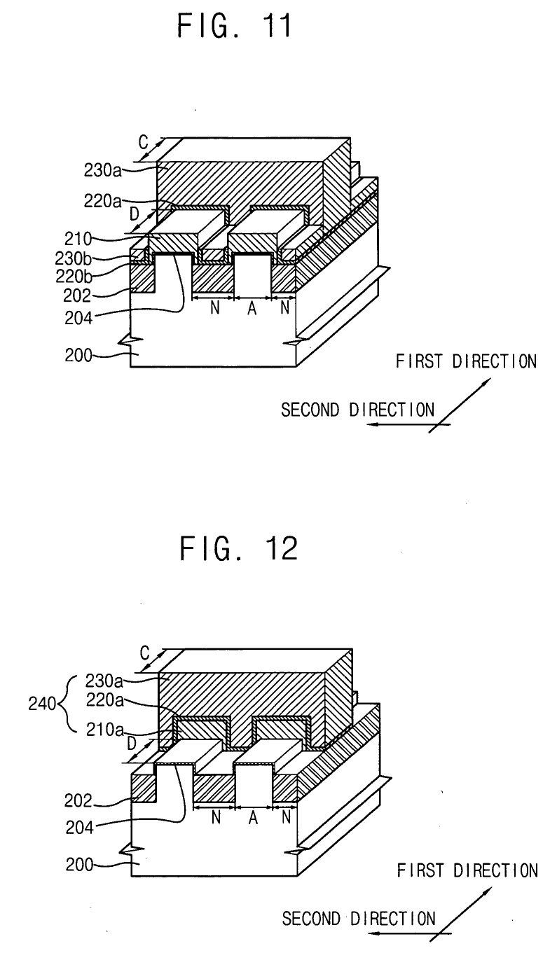

As shown in FIG. 9, the substrate 200 is also divided into regions C and D, which extend lengthwise in the second direction. As shown in FIG. 12, a memory cell 240 of the nonvolatile semiconductor will be formed in region C.

Returning to FIG. 9, a preliminary floating gate 210 is formed on the substrate 200 to enclose the gate oxide layer 204. The preliminary floating gate 210 may be formed using polysilicon doped with impurities. Since the preliminary floating gate 210 encloses the gate oxide layer 204, which is formed on the upper portion and a sidewall of the active region A, a portion of the preliminary floating gate 210 is disposed above the recessed isolation layer 202. Thus, the width of the preliminary floating gate 210 is greater than that of the active region A. The thickness of the preliminary floating gate 210 is greater than that of the recessed isolation layer 202.

Next, a dielectric layer 220 having an ONO structure is formed on the substrate 200. The dielectric layer 220 includes a lower oxide layer, a nitride layer, and an upper oxide layer that are sequentially formed on the substrate 200 to cover the preliminary floating gate 210. The upper and lower oxide layers may include silicon oxide, and the nitride layer may include silicon nitride. In some embodiments of the invention, the upper and lower oxide layers may be formed using a thermal oxidation process.

A control gate layer 230 is then formed on the dielectric layer 220, the control gate layer having a thickness that is sufficient to completely fill the gap between the preliminary floating gates 210.

Referring to FIG. 10, the control gate layer 230 is etched until a portion of the dielectric layer 220 is exposed, simultaneously forming a control gate 230a and a first remaining pattern 230b on the dielectric layer 220. The first remaining pattern 230b is formed over the recessed isolation layer 202 between the preliminary floating gates 210. The first remaining pattern 230b may partially fill the gap between the preliminary floating gates 210. Preferably, the first remaining pattern 230b has a thickness of about 50 to about 150 Å.

The control gate 230a extends lengthwise along the second direction, whereas the first remaining pattern 230b extends lengthwise along the first direction. Meanwhile, the control gate 230a is positioned in region C of the substrate 200 and the first remaining pattern 230b is positioned in region D of the substrate.

Referring to FIG. 11, the exposed portion of the dielectric layer 220 is etched until the preliminary floating gate 210 positioned in region D is exposed, simultaneously forming a dielectric layer pattern 220a and a second remaining pattern 220b. The exposed portion of the dielectric layer 220 may be partially removed by a dry etching process. The dielectric layer pattern 220a is positioned in the first region C and the second remaining pattern 220b is positioned in the second region D. The second remaining pattern 220b is formed between the first remaining pattern 230b and the recessed isolation layer 202 and between sidewalls of the preliminary floating gate 210 and the first remaining pattern 230b.

Referring to FIG. 12, the exposed portion of the preliminary floating gate 210, the first remaining pattern 230b, and the second remaining pattern 220b are etched until the gate oxide layer 204 and the recessed isolation layer 202 are exposed. Thus, a floating gate 210a is formed on the gate oxide layer 204 and under the control gate 203a. The floating gate 210a is located both in region C and in the active region A.

When the floating gate 210a is formed beneath the dielectric layer pattern 220a, a stacked memory cell 240 of the nonvolatile semiconductor memory device is completed. The stacked memory cell 240 includes the control gate 230a, the dielectric layer pattern 220a, and the floating gate 210a. Like the embodiments described above, because the stacked memory cell 240 does not exhibit voids or punch-throughs, leakage currents may be suppressed.

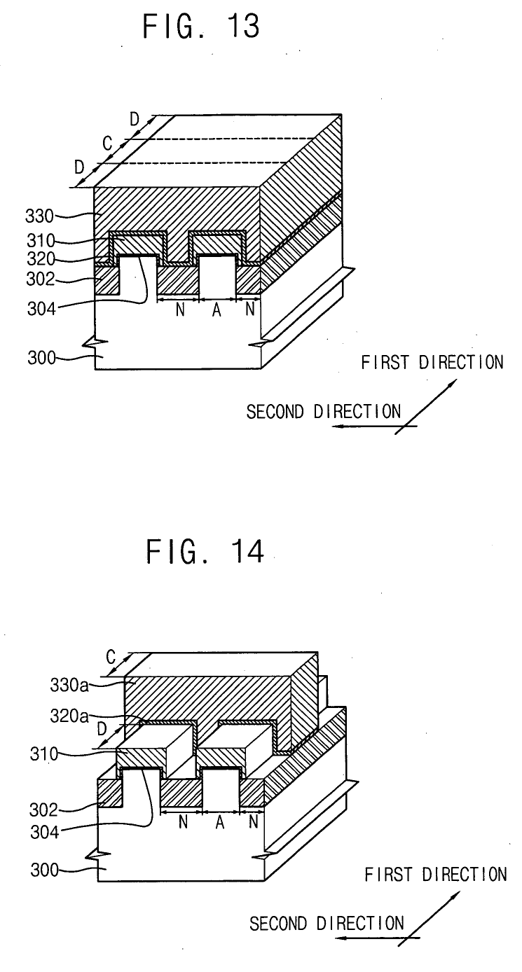

FIGS. 13 to 16 are perspective diagrams illustrating a method of manufacturing a nonvolatile semiconductor memory device in accordance with some embodiments of the invention.

Referring to FIG. 13, a preliminary floating gate 310, a dielectric layer 320, and a control gate layer 330 are sequentially formed on a substrate 300 on which a recessed isolation layer 302 and a gate oxide layer 304 are formed. The recessed isolation layer 302, the gate oxide layer 304, the preliminary floating gate 310, the dielectric layer 320, and the control gate layer 330 are formed using processes substantially identical to those described with reference to FIGS. 8 and 9.

Referring to FIG. 14, after an etching mask (not shown) is formed on the control gate layer 330, portions of the control gate layer 330 and the dielectric layer 320 exposed by the etching mask are sequentially etched until a portion of the recessed isolation layer 302 positioned in a region D is exposed. The control gate layer 330 and the dielectric layer 320 may be partially etched by a dry etching process. Thus, a control gate 330a and a dielectric layer pattern 320a are simultaneously formed in region C of the substrate 300.

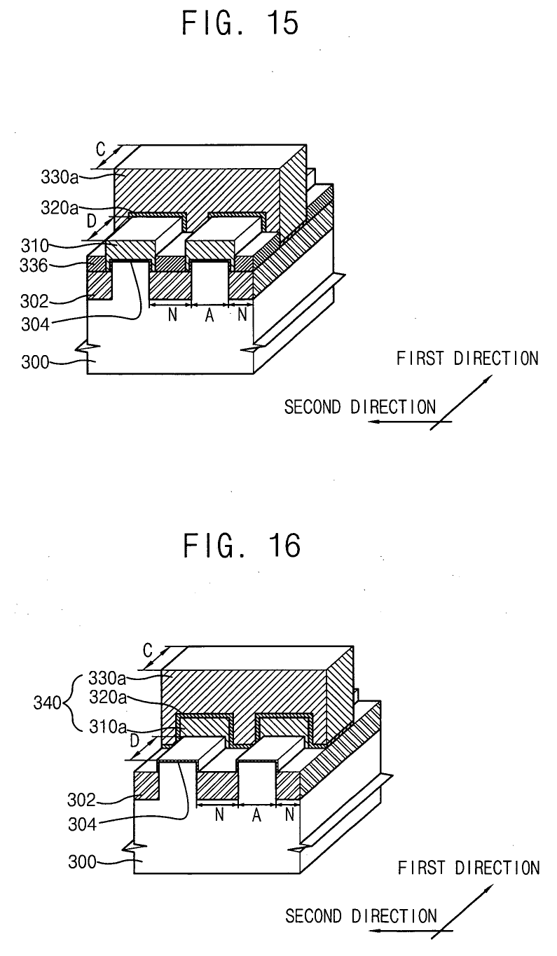

Referring to FIG. 15, a photoresist film (not shown) is formed on the substrate 300 to cover the control gate 330a and the dielectric layer pattern 320a.

The photoresist film is exposed and developed so that a photoresist pattern 336 is formed on a portion of the recessed isolation layer 302 positioned in the region D of the substrate 300. The photoresist pattern 336 is a sacrificial pattern that prevents the recessed isolation layer 302 from being damaged in a subsequent etching process.

Referring to FIG. 16, a portion of the preliminary floating gate 310 formed in the region D and the photoresist pattern 336 are etched until the gate oxide layer 304 and the recessed isolation layer 302 are exposed. Accordingly, a floating gate 310a is formed in the first region C and an active region A of the substrate 300. As a result, a stacked memory cell 340 of the nonvolatile semiconductor memory device is completed on the substrate 300. The stacked memory cell 340 includes the control gate 330a, the dielectric layer pattern 320a, and the floating gate 310a. Like the embodiments described above, because the stacked memory cell 240 does not exhibit voids or punch-throughs, leakage currents may be avoided.

The invention may be practiced in many ways. What follows are exemplary, non-limiting descriptions of some embodiments of the invention.

According to some embodiments, a method of manufacturing a nonvolatile semiconductor memory device includes forming a preliminary floating gate on a substrate having an active region and an inactive region both of which extend in a first direction. A dielectric layer and a control gate layer are sequentially formed on the substrate to cover the preliminary floating gate. A control gate, a dielectric layer pattern, and a remaining pattern structure are formed by partially etching the control gate layer and the dielectric layer until the preliminary floating gate is partially exposed. The control gate extends in a second direction. A floating gate is formed on the active region by etching the remaining pattern structure and a portion of the preliminary floating gate exposed by the control gate until the substrate is exposed.

According to some embodiments, the inactive region is defined by forming an isolation layer having an upper surface that is lower than an upper surface of the active region.

According to some embodiments, the height of the isolation layer is less than that of the preliminary floating gate.

According to some embodiments, the preliminary floating gate extends along the first direction, and the preliminary floating gate encloses an upper portion of the active region.

According to some embodiments, the dielectric layer is disposed continuously on an upper face of the floating gate, a sidewall of the floating gate, and the inactive region.

According to some embodiments, the dielectric layer includes a first oxide layer, a nitride layer, and a second oxide layer, where the first and the second oxide layers are formed by a thermal oxidation process or a radical oxidation process.

According to some embodiments, the first direction is substantially perpendicular to the second direction.

According to some embodiments, the remaining pattern structure includes a first remaining pattern and a second remaining pattern. The first remaining pattern may be formed by etching the control gate layer, and the second remaining pattern may be formed by etching the dielectric layer. The first remaining pattern and the control gate may be simultaneously formed, and the second remaining pattern and the dielectric layer pattern may be simultaneously formed.

According to some embodiments, a method of manufacturing a nonvolatile semiconductor memory device includes forming a preliminary floating gate on a substrate having an active region and an inactive region that extend in a first direction to enclose an upper portion of the active region. The substrate is also divided into a first region and a second region. The inactive region has an upper surface that is lower than an upper surface of the active region. A dielectric layer and a control gate layer are sequentially formed on the substrate to cover the preliminary floating gate. A control gate and a first remaining pattern are formed by etching the control gate layer. The control gate is positioned in the first region and extends in a second direction, and the first remaining pattern is positioned in the second region and the inactive region. A dielectric layer pattern and a second remaining pattern are formed by partially etching the dielectric layer exposed by the control gate. The dielectric layer pattern is positioned in the first direction and extends in the second direction. The second remaining pattern is positioned in the second region beneath the first remaining pattern. A floating gate is formed in the active region along the first region by etching the preliminary floating gate, the first remaining pattern and the second remaining pattern until the substrate is exposed.

According to some embodiments, a memory cell of the nonvolatile semiconductor device is formed on the first region, and the preliminary floating gate, the dielectric layer, and the control gate layer are etched away from the second region.

According to some embodiments, the preliminary floating gate is etched until the first remaining pattern has a height of about 50 to about 150 Å.

According to other embodiments of the invention, a method of manufacturing a nonvolatile semiconductor memory device includes forming a preliminary floating gate on a substrate having an active region and an inactive region that extend in a first direction. A dielectric layer and a control gate layer are sequentially formed on the substrate to cover the preliminary floating gate. A control gate and a dielectric layer pattern are formed by etching the control gate layer and the dielectric layer until the preliminary floating gate is exposed. The control gate and the dielectric layer pattern extend in a second direction. A sacrificial pattern is formed on the inactive region exposed by the control gate. A floating gate is formed on the active region by etching the sacrificial layer and the preliminary floating gate exposed by the control gate until the substrate is exposed.

According to some embodiments, the inactive region is defined by an isolation layer having an upper surface that is substantially lower than that of the active region.

According to some embodiments, the preliminary floating gate is located in the active region, and the preliminary floating gate has a height that is substantially higher than that of the isolation layer.

According to some embodiments, the preliminary floating gate extends in the first direction and the preliminary floating gate encloses an upper portion of the active region.

According to some embodiments, in order to form the control gate and the dielectric layer pattern of the memory cell, an etching mask is formed on the control gate layer. The etching mask extends in the second direction. The memory cell includes the control gate, the dielectric layer pattern, and the floating gate. The control gate is formed by partially etching the control gate layer exposed by the etching mask. The dielectric layer pattern is formed by etching the dielectric layer exposed by the etching mask.

According to some embodiments, forming the sacrificial pattern includes forming a photoresist film on the substrate to cover the dielectric layer pattern and the control gate, and selectively removing portions of the photoresist film.

According to some embodiments of the invention, a remaining pattern or a photoresist pattern functions as a sacrificial layer to prevent an isolation layer from being damaged in subsequent etching processes for forming a floating gate, where the floating gate has a height that is greater than a height of the isolation layer. Thus, voids or punch-throughs may be prevented in the isolation layer, and leakage currents avoided. As a result, the nonvolatile semiconductor memory device that includes the isolation layer may have good electrical characteristics.

Having thus described exemplary embodiments of the present invention, it is to be understood that the invention defined by the appended claims is not to be limited by particular details set forth in the above description as many apparent variations thereof are possible without departing from the spirit or scope thereof as hereinafter claimed.

1. A method of manufacturing a nonvolatile semiconductor memory device comprising:
forming a preliminary floating gate on a substrate, the substrate having an active region and an inactive region that extend in a first direction;
forming a dielectric layer to cover the preliminary floating gate;
forming a control gate layer to cover the dielectric layer;
etching the control gate layer and the dielectric layer until the preliminary floating gate is exposed to form a control gate, a dielectric layer pattern, and a remaining pattern structure, the control gate extending in a second direction; and
etching the remaining pattern structure and a portion of the preliminary floating gate until the substrate is exposed to form a floating gate on the active region.

2. The method of claim 1, further comprising defining the inactive region by forming an isolation layer having an upper surface that is lower than an upper surface of the active region.

3. The method of claim 2, wherein forming the isolation layer comprises forming the isolation layer to a height that is lower than a height of the preliminary floating gate.

4. The method of claim 1, wherein forming the preliminary floating gate comprises forming the preliminary floating gate to extend along the first direction and to enclose an upper portion of the active region.

5. The method of claim 1, wherein forming the dielectric layer comprises forming the dielectric layer to be continuous along an upper face of the floating gate, a sidewall of the floating gate, and the inactive region.

6. The method of claim 5, wherein forming the dielectric layer further comprises:
forming a first oxide layer using a thermal oxidation process or a radical oxidation process;
forming a nitride layer on the first oxide layer; and
forming a second oxide layer on the nitride layer using a thermal oxidation process or a radical oxidation process.

7. The method of claim 1, wherein the first direction is substantially perpendicular to the second direction.

8. The method of claim 1, wherein etching the control gate layer and the dielectric layer to form the remaining pattern structure comprises etching the control gate layer and the dielectric layer to form a first remaining pattern and a second remaining pattern.

9. The method of claim 8, wherein etching the control gate layer and the dielectric layer to form the first remaining pattern and the second remaining pattern comprises:
etching the control gate layer to form the first remaining pattern; and
etching the dielectric layer to form the second remaining pattern.

10. The method of claim 9, wherein the first remaining pattern and the control gate are simultaneously formed, and wherein the second remaining pattern and the dielectric layer pattern are simultaneously formed.

11. A method of manufacturing a nonvolatile semiconductor memory device comprising:
forming a preliminary floating gate on a substrate having an active region, an inactive region, a first region, and a second region, the inactive region having an upper surface that is lower than an upper surface of the active region, the preliminary floating gate extending in a first direction and enclosing an upper portion of the active region;
forming a dielectric layer to cover the preliminary floating gate;
forming a control gate layer to cover the dielectric layer;
etching the control gate layer to form a control gate and a first remaining pattern, the control gate disposed in the first region and extending in a second direction, the first remaining pattern disposed in the second region and in the inactive region;
etching the dielectric layer to form a dielectric layer pattern and a second remaining pattern, the dielectric layer pattern disposed in the first region and extending in the second direction, the second remaining pattern disposed in the second region beneath the first remaining pattern; and
etching the preliminary floating gate, the first remaining pattern, and the second remaining pattern until the substrate is exposed to form a floating gate in the active region and in the first region.

12. The method of claim 11, further comprising defining the inactive region with an isolation layer, the preliminary floating gate having a height that is greater than a height of the isolation layer.

13. The method of claim 11, further comprising:
etching the preliminary floating gate, the dielectric layer, and the control gate layer from the second region to form a memory cell of the nonvolatile semiconductor device on the first region.

14. The method of claim 11, wherein etching the preliminary floating gate comprises etching the preliminary floating gate until the first remaining pattern has a height of about 50 to about 150 Å.

15. A method of manufacturing a nonvolatile semiconductor memory device comprising:
forming a preliminary floating gate on a substrate, the substrate having an active region and an inactive region that extend in a first direction;
forming a dielectric layer to cover the preliminary floating gate;
forming a control gate layer to cover the dielectric layer;
etching the control gate layer and the dielectric layer until the preliminary floating gate is exposed to form a control gate and a dielectric layer pattern that extend in a second direction;
forming a sacrificial pattern on the inactive region; and
etching the sacrificial pattern and the preliminary floating gate until the substrate is exposed to form a floating gate that is disposed on the active region.

16. The method of claim 15, further comprising defining the inactive region with an isolation layer having an upper surface that is lower than an upper surface of the active region.

17. The method of claim 16, wherein forming the preliminary floating gate comprises forming the preliminary floating gate in the active region, wherein the preliminary floating gate has a height that is greater than a height of the isolation layer.

18. The method of claim 15, wherein forming the preliminary floating gate comprises forming the preliminary floating gate to extend in the first direction and to enclose an upper portion of the active region.

19. The method of claim 15, wherein etching the control gate layer and the dielectric layer comprises:
forming an etching mask on the control gate layer, the etching mask extending in the second direction and defining a memory cell of the nonvolatile semiconductor device, the memory cell including the control gate, the dielectric layer pattern, and the floating gate;
partially etching the control gate layer exposed by the etching mask to form the control gate; and
partially etching the dielectric layer exposed by the etching mask to form the dielectric layer pattern.

20. The method of claim 15, wherein forming the sacrificial pattern comprises:
covering the dielectric layer pattern and the control gate with a photoresist film; and
removing portions of the photoresist film to form the sacrificial pattern on the isolation layer.
